(19) United States
(12) Patent Application Publication
(10) Pub. No.: US 2023/0005803 A1
(43) Pub. Date: Jan. 5, 2023

(54) METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Giovanni GRAZIOSI, Vimercate (MB) (IT); Michele DERAI, Milano (IT)

(73) Assignee: STMicroelectronics S.r.l., Agrate Brianza (MB) (IT)

(21) Appl. No.: 17/847,824

(22) Filed: Jun. 23, 2022

(30) Foreign Application Priority Data
Jun. 30, 2021 (IT) 102021000017213

(51) Int. Cl. H01L 23/31; H01L 23/495; H01L 23/29

(52) U.S. Cl. CPC H01L 23/3107; H01L 23/49513; H01L 23/298

(57) ABSTRACT

A semiconductor chip is arranged on a first surface of a die pad in a substrate (leadframe) including an array of electrically conductive leads. An encapsulation of laser direct structuring (LDS) material encapsulates the substrate and the semiconductor chip. The encapsulation has a first surface, a second surface opposed to the first surface and a peripheral surface. The array of electrically conductive leads protrude from the peripheral surface with areas of the second surface of the encapsulation arranged between adjacent leads. LDS structured areas of the second surface located between adjacent leads in the array of electrically conductive leads provide a further array of electrically conductive leads exposed at the second surface. First and second electrically conductive vias extending through the encapsulation material as well as electrically conductive lines over the encapsulation material provide an electrical bonding pattern between the semiconductor chip and selected ones of the leads.

### PRIORITY CLAIM

This application claims the priority benefit of Italian Application for Patent No. 102021000017213, filed on Jun. 30, 2021, the content of which is hereby incorporated by reference in its entirety to the maximum extent allowable by law.

### TECHNICAL FIELD

The description relates to semiconductor devices.

Embodiments as discussed herein can be applied to semiconductor devices for the automotive and mass-market sectors, for instance.

### BACKGROUND

Increasing complexity in semiconductor device packages oftentimes translates into an increased number of input/output (I/O) pins.

This may be the case, for instance, for the semiconductor device packages of the type currently referred to as quad-flat package (QFP).

In conventional approaches, increasing the I/O number leads to increasing the package footprint.

This may be undesirable for various applications.

Providing additional leads that are bent inward, near the package plastic body, may be considered as a way of increasing the I/O number without correspondingly increasing the package footprint.

Such an approach has a basic disadvantage in that it requires an additional complex bending process.

There is a need in the art to contribute in overcoming the drawbacks outlined above.

### SUMMARY

One or more embodiments may relate to a method.

One or more embodiments may relate to a corresponding semiconductor device.

A semiconductor device of the QFP type for use in the automotive and mass-market sectors may be exemplary of such a device.

One or more embodiments provide a semiconductor device (essentially of the QFP type) comprising additional leads at the rear or bottom side.

In one or more embodiments, these additional leads are electrically coupled to one or more semiconductor chips by through-mold-vias (TMVs) extending in a molding compound providing package encapsulation.

Laser direct structuring (LDS) processing can be used to form these vias as well as further electrical connections to the chip or chips.

One or more embodiments may provide advantages such as: the I/O number can be increased maintaining the same package dimensions; a same I/O number can be achieved with a reduction in package sizes; and a simple process is provided in comparison with lead bending.

Briefly, one or more embodiments facilitate increasing the I/O number with a simple process (LDS processing, for instance).

One or more embodiments facilitate, for instance, providing LDS-based multiple-row QFP packages with a higher I/O number maintaining a same device footprint or even reducing the device footprint.

The adoption of one or more embodiments can be detected through external visual inspection and cross-section through a semiconductor device.

### BRIEF DESCRIPTION OF THE DRAWINGS

One or more embodiments will now be described, by way of example only, with reference to the annexed figures, wherein:

FIG. 1 is a plan view from the bottom or back side of a semiconductor device as described herein,

FIG. 2 is a cross-sectional view along line II-II of FIG. 1, exemplary of a possible implementation of embodiments,

FIG. 3 is a cross-sectional view substantially corresponding to the cross-sectional view of FIG. 2, illustrative of an alternative implementation of embodiments, and

FIGS. 4A to 4G are illustrative of possible steps in manufacturing a semiconductor device as illustrated in FIG. 3.

### DETAILED DESCRIPTION

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

Quad-flat package (QFP) is a current designation for a surface-mounted integrated circuit package with leads (possibly of the “gull-wing” type) extending from its sides.

The designation “multi-row package” may apply to a semiconductor device package having multiple rows of leads. Multiple rows of leads facilitate increasing the I/O number while maintaining (or possibly even reducing) the package footprint.

In fact, QFP packages may exhibit limited flexibility in a current distribution complying with the specifications underlying the wire bonding process. Also, in a current QFP design, a metal pad is left exposed at the back or bottom side of the package for a thermal dissipation, with the pad intended to be soldered on support substrate such as a printed circuit board (PCB).

A QFP package may thus have a limited I/O number, which leads to a package size increase in case the I/O number is increased.

An attempt to overcome such a constraint in terms of interconnection layout and package size can be made by resorting to an unconventional QFP package comprising additional leads bent inwards near the package plastic body.

For instance, additional leads can be coupled with standard leads in the QFP package using the free space between these latter in order to increase the I/O number keeping a same package size.

Such an approach is inevitably related to a fairly complex bending process used to create added leads.

Laser direct structuring or LDS technology is a laser-based technology now currently used in manufacturing semiconductor devices. Using LDS technology, electrically conductive formations such as lines and vias can be formed in an otherwise insulating molding compound via laser beam activation or “structuring”, possibly followed by plating.

Laser direct structuring or LDS technology (oftentimes referred to also as direct copper interconnection (DCI) technology) is discussed, for instance, in documents such as United States Patent Application Publication Nos. 2018/0342453, 2020/0203264, 2020/0321274, 2021/0050226 or 2021/0050299, all of which are incorporated herein by reference.

In the examples described herein, LDS processing is used to create additional interconnections in a semiconductor device package.

In that way, the I/O number in a package such as a QFP package can be increased by keeping a same package size (or possibly even reducing the package side) in a simple, easy, and reproducible way.

The examples discussed herein retain the basic structure of a semiconductor device package such as a QFP package adapted to be mounted on a support substrate S such as a printed circuit board (PCB), for instance.

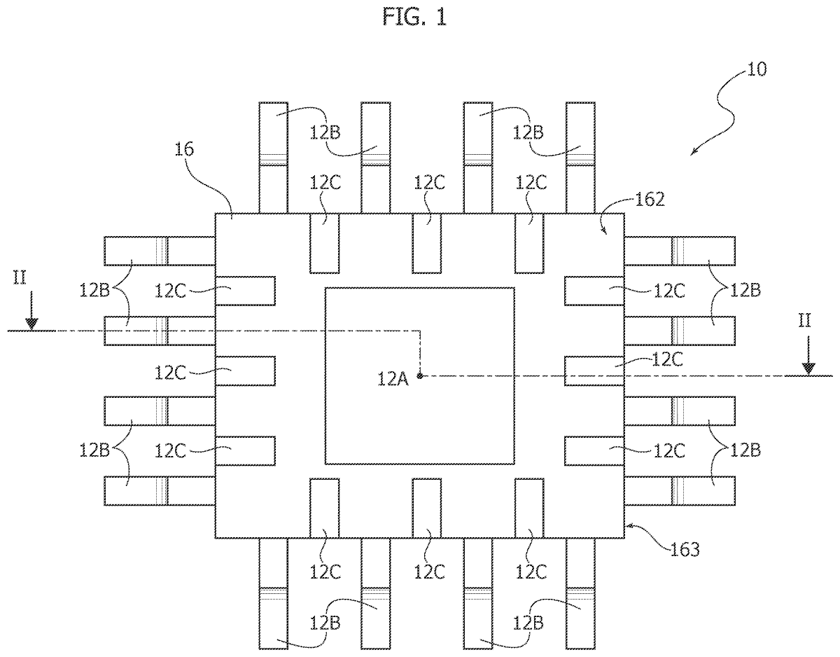

As illustrated in FIGS. 1 to 3, such a device 10 comprises a leadframe 12 including: a die pad 12A onto which one or more semiconductor integrated circuit chips or dies 14 (only one is illustrated for simplicity) can be arranged; and an array of leads 12B extending from the sides of the device package.

Attachment of the chip or die 14 to the die pad 12A is via die attach material 14A (“glue”), as conventional in the art.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Leadframes are conventionally created using technologies such as a photo-etching technology. With this technology, metal (e.g., copper) material in the form of a foil or tape is etched on the top and bottom sides to create various pads and leads.

An insulating encapsulation 16 is molded onto the leadframe 12A, 12B having the chip or die 14 arranged thereon, leaving—as visible in FIG. 1, for instance—the die pad 12A exposed at the bottom or back surface of the device 10 in view of soldering to the substrate S to facilitate thermal dissipation with the leads 12B extending from the sides of the package.

As illustrated, the encapsulation 16 has: a first surface 161 at the top or front side of the package of the device 10; a second surface 162 (opposed to the first surface 161) at the bottom or back side of the package of the device 10; and a peripheral side surface 163 extending between the first surface 161 and the second surface 162.

Unless otherwise indicated, a structure as discussed in the foregoing is conventional in the art, which makes it unnecessary to provide a more detailed description herein.

The examples described here take advantage of the possibility of using LDS material for the encapsulation 16.

In that way, additional leads 12C in the form of through mold vias (TMVs) provided by LDS processing (laser beam activation usually followed by plating) at the back or bottom side/surface 162 of the encapsulation 16.

In that way, additional (partial) leads 12C can be formed that are exposed at the back or bottom surface 162 of the package around the die pad 12A.

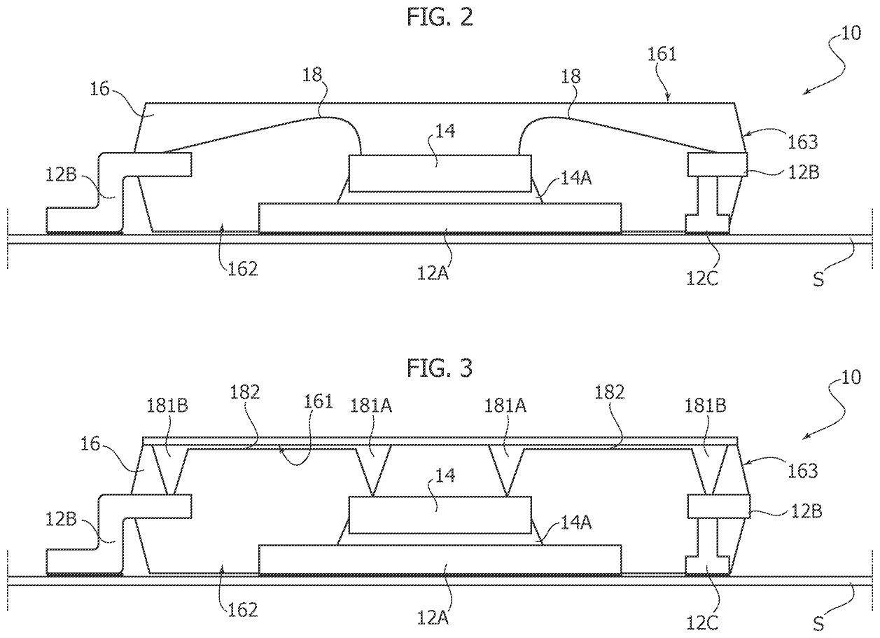

As exemplified in FIG. 2, both the “standard” leads 12B protruding from the side surface 163 of the encapsulation 16 and the “additional” leads 12C at the back surface 162 of the encapsulation 16 can be electrically connected to the die via a conventional wire bonding pattern, as indicated at 18 in FIG. 2.

The encapsulation 16 being comprised of LDS material can be otherwise exploited to provide electrically conductive formations between the leads 12B, 12C and the die or dice 14.

As illustrated, these electrically conductive formations (again produced via a laser beam processing and plating, for instance) comprise: (further) vias 181A, 181B formed at the leads 12B, 12C and at the chip or chips 14 in the portion of the encapsulation 16 adjacent the top or front surface 161 of the encapsulation; and a pattern of electrically conductive lines or tracks 182 extending over the top or front surface 161 of the encapsulation and connecting selected ones of the vias 181A, 181B according to a desired signal routing pattern.

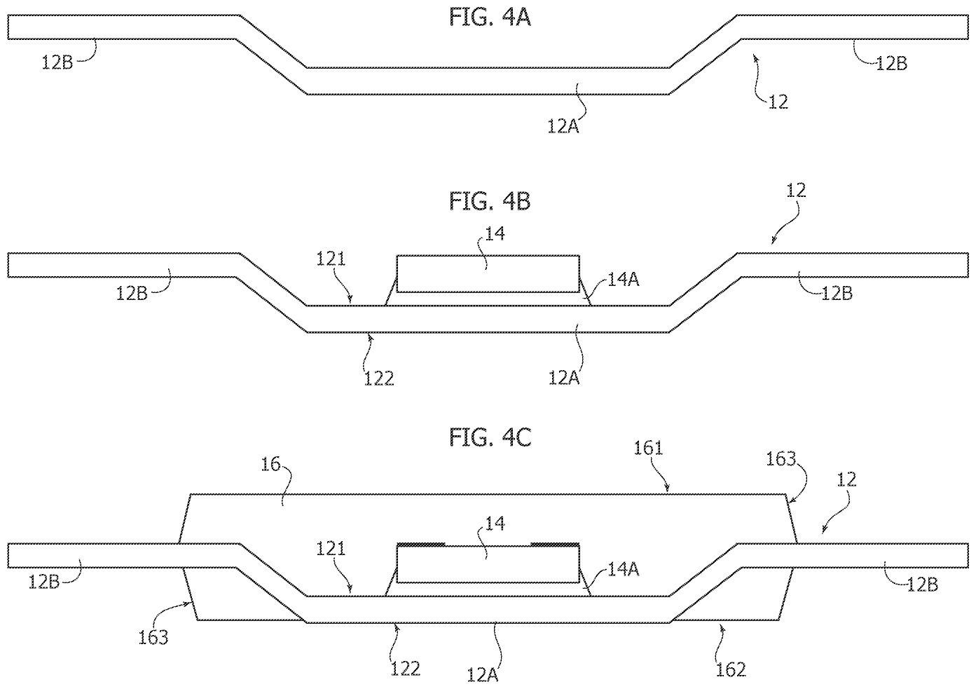

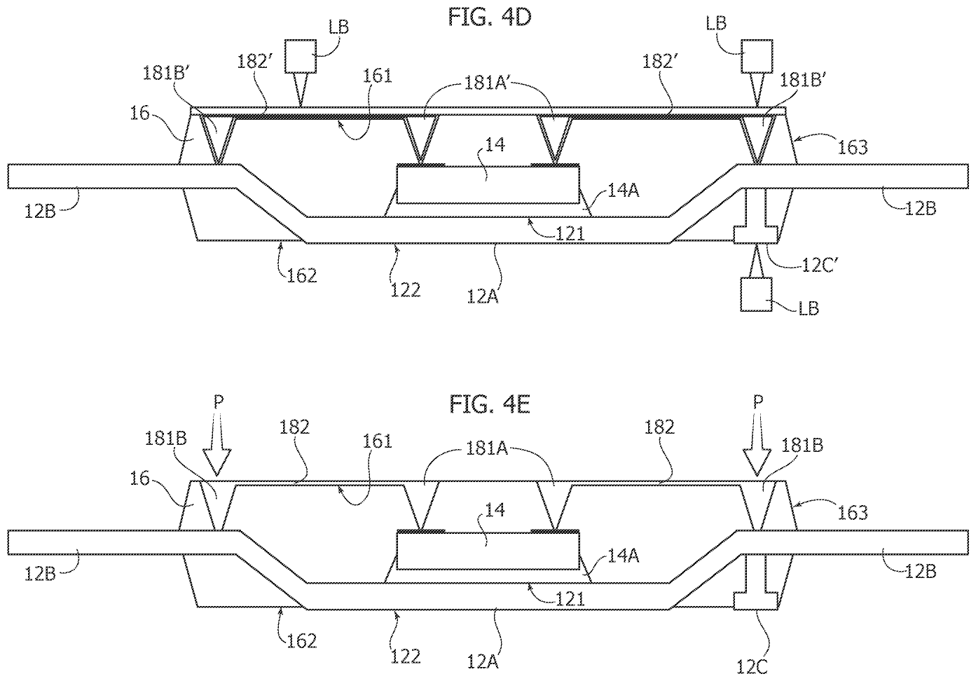

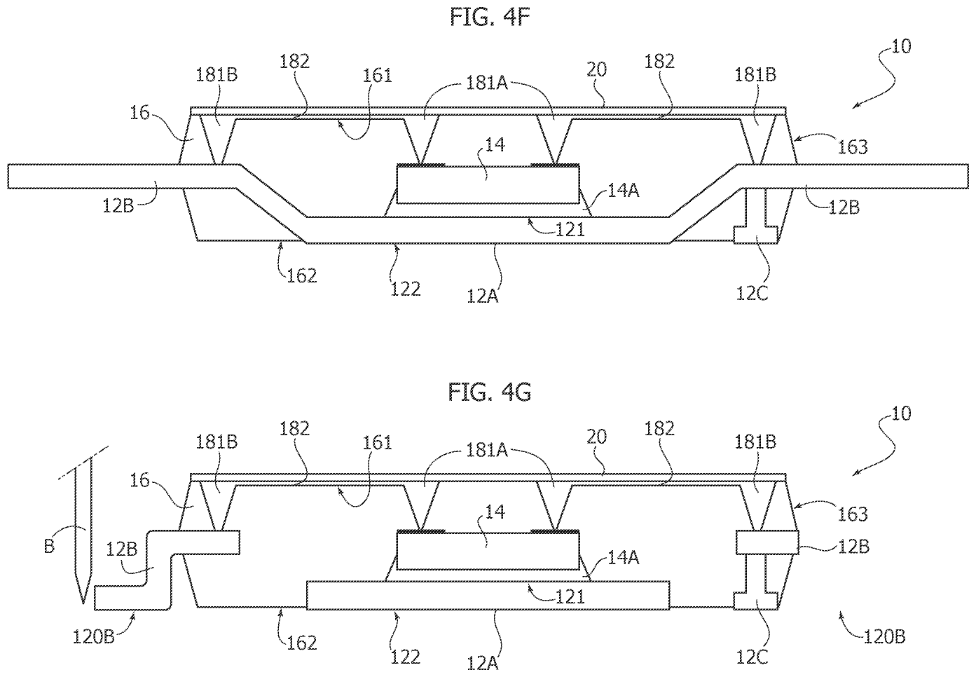

FIGS. 4A to 4G are illustrative of a possible sequence of steps in manufacturing a semiconductor device 10 according to the “full LDS” implementation exemplified in FIG. 3.

Those of skill in the art will otherwise appreciate that the sequence of steps of FIGS. 4A to 4G is merely exemplary in so far as: one or more steps illustrated can be omitted, performed in a different manner (with other tools, for instance) and/or replaced by other steps; additional steps may be added; and/or one or more steps can be carried out in a sequence different from the sequence illustrated.

Also, for the sake of simplicity and ease of understanding, unless the context indicates otherwise, like parts or elements are indicated throughout FIGS. 4A to 4G with like reference symbols; for brevity a corresponding description will not be repeated for each and every figure.

FIG. 4A is exemplary of the provision of a (standard, e.g., gull-wing) leadframe 12 including a die pad 12A and an array of leads 12B.

FIG. 4B is exemplary of the attachment of a semiconductor chip or die 14 at a first surface 121 of the die pad 12A. This may occur, as conventional in the art, via die attach material 14A.

Plural semiconductor chips or dice 14 can be arranged at the first surface 121 of the die pad 12A: one chip or die 14 is illustrated here for simplicity.

FIG. 4C is exemplary of an encapsulation 16 of LDS material being molded onto the structure of the FIG. 4B.

The step of FIG. 4C can be implemented in a manner known per se via additive transfer molding by leaving a second surface 122 (opposed to the first surface 121) of the die pad 12A exposed at the bottom or back surface 162 of the encapsulation 16/package 10.

FIG. 4C is thus exemplary of encapsulating the substrate 12 with the semiconductor chip 14 arranged thereon in an encapsulation 16 of laser direct structuring (LDS) material.

As illustrated, the encapsulation has a first surface 161, a second surface 162 opposed to the first surface 161, and a peripheral surface 163 between the first surface 161 and the second surface 162.

As illustrated, the die pad 12A has a second die pad surface 122 (opposed to the first die pad surface 121 onto which the chip 14 is attached) left exposed at the second surface 162 of the encapsulation 16 with the array of electrically conductive leads 12B protruding from the peripheral surface 163 of the encapsulation.

As visible in FIG. 1, areas of the second surface 162 of the encapsulation 16 are located between adjacent leads 12B in the array of electrically conductive leads 12B.

FIG. 4D is exemplary of the application of laser beam energy (as schematically represented at LB) to “structure” in the LDS material of the encapsulation 16: first vias intended to provide the “additional” leads 12C at the bottom or back surface 162 of the encapsulation 16; further vias 181A, 181B at the top or front surface 161 of the encapsulation 16; and the lines or tracks 182 electrically connecting the vias 181A, 181B according to a desired signal routing pattern.

In FIG. 4D, reference numbers with accents (namely 12C′, 181A′, 181B′ and 182′) are used to designate the result of laser beam structuring that (according to current LDS technology) is completed via a plating step as exemplified at P in FIG. 4E to facilitate electrical conductivity of the vias (leads) 12C, 181A, 181B and of the lines or tracks 182.

As illustrated, applying LDS processing to the encapsulation 16 of LDS material thus comprises: applying laser beam energy LB to the encapsulation 16 of LDS material to provide therein laser-activated regions such as the vias 12C′, 181A′, 181B′ and the lines or tracks 182′; and growing (via plating P, for instance) electrically conductive material at the laser-activated regions 12C′, 181A′, 181B′, and 182′.

FIGS. 4D and 4E are thus exemplary of LDS processing applied to areas of the second surface 162 of the encapsulation 16 of LDS material located between adjacent leads 12B to structure in the LDS material a further array of electrically conductive leads 12C exposed at the second surface 162 of the encapsulation 16 around the die pad 12A.

FIGS. 4D and 4E are also exemplary of providing an electrical bonding pattern 181A, 181B, 182 between the semiconductor chip 14 and selected ones of the adjacent leads 12B in the array of electrically conductive leads and in the further array of electrically conductive leads 12C.

More specifically, FIGS. 4D and 4E are exemplary of the possibility of providing such an electrical bonding pattern (as an alternative to a conventional wire bonding pattern as illustrated at 18 in FIG. 2) applying LDS processing to the first surface 161 of the encapsulation 16 of LDS material.

As illustrated, such LDS processing comprises structuring in the LDS material of the encapsulation 16: first electrically conductive vias 181A extending through the encapsulation material 16 between the first surface 161 of the encapsulation 16 and selected ones of the adjacent leads 12B in the array of electrically conductive leads 12B and in the further array of electrically conductive leads 12C; second electrically conductive vias 181B extending through the encapsulation material 16 between the first surface 161 of the encapsulation 16 and the semiconductor chip 14; and a routing of electrically conductive lines 182 electrically coupling selected ones of the first vias 181A with selected ones of the second vias 181B.

FIG. 4F is exemplary of the deposition of a passivation layer 20 over the front or top surface of the package.

Finally, FIG. 4G is exemplary of final processing such as dam-bar cutting, trimming and forming (shaping) the leads 12B.

As illustrated, such forming or shaping comprises bending the leads 12B in the array of electrically conductive leads protruding from the peripheral surface 163 the encapsulation 16 to provide distal lead portions 120B substantially co-planar with the further array of electrically conductive leads 12C exposed at the second surface 162 of the encapsulation 16 (and with the second surface 122 of the die pad 12A).

Also, reference is generally made in FIG. 4G to a possible “singulation” step (via a sawing blade B, for instance) where plural devices manufactured simultaneously—as conventional in the art—are finally separated into individual devices 10.

Without prejudice to the underlying principles, the details and embodiments may vary, even significantly, with respect to what has been described in the foregoing, by way of example only, without departing from the extent of protection.

The claims are an integral part of the technical teaching provided herein in respect of the embodiments.

The extent of protection is determined by the annexed claims.

1. A method, comprising:
arranging a semiconductor integrated circuit chip on a first surface of a die pad in a substrate, the substrate comprising an array of first electrically conductive leads extending away from the die pad;
encapsulating the substrate and semiconductor integrated circuit chip in an encapsulation of laser direct structuring (LDS) material, wherein the encapsulation has a first surface, a second surface opposed to the first surface and a peripheral surface between the first surface and the second surface, wherein the array of first electrically conductive leads protrudes from the peripheral surface of the encapsulation with areas of the second surface of the encapsulation arranged between adjacent ones of the first electrically conductive leads; and
applying LDS processing to areas of the second surface of the encapsulation located between adjacent ones of the first electrically conductive leads to structure therein an array of second electrically conductive leads exposed at the second surface of the encapsulation.

2. The method of claim 1, wherein the die pad has a second die pad surface opposed to the first die pad surface, the second die pad surface left exposed at the second surface of the encapsulation, and wherein the array of second electrically conductive leads is arranged around the second die pad surface.

3. The method of claim 1, further comprising providing an electrical connection pattern between the semiconductor integrated circuit chip and the array of first electrically conductive leads and the array of second electrically conductive leads.

4. The method of claim 1, further comprising providing a wire bonding pattern between the semiconductor integrated circuit chip and the array of first electrically conductive leads and the array of second electrically conductive leads.

5. The method of claim 1, further comprising applying LDS processing to the first surface of the encapsulation of LDS material to structure therein:
first electrically conductive vias extending through the encapsulation material between the first surface of the encapsulation and selected ones of the leads in one or more of the array of first electrically conductive leads and the array of second electrically conductive leads;
second electrically conductive vias extending through the encapsulation material between the first surface of the encapsulation and the semiconductor integrated circuit chip; and
a routing of electrically conductive lines electrically coupling selected ones of the first electrically conductive vias with selected ones of the second electrically conductive vias.

6. The method of claim 1, wherein applying LDS processing comprises:
applying laser beam energy to the encapsulation of LDS material to provide laser-activated regions therein; and
growing electrically conductive material at the laser-activated regions.

7. The method of claim 1, further comprising bending the array of first electrically conductive leads protruding from the peripheral surface the encapsulation to provide lead distal portions substantially co-planar with the array of second electrically conductive leads exposed at the second surface of the encapsulation.

8. The method of claim 1, further comprising trimming the first electrically conductive leads protruding from the peripheral surface the encapsulation.

9. The method of claim 1, the substrate comprising an array of third electrically conductive leads extending away from the die pad, and wherein the array of second electrically conductive leads exposed at the second surface of the encapsulation are in contact with the third electrically conductive leads.

10. The method of claim 1, further comprising trimming the third electrically conductive leads at the peripheral surface the encapsulation.

11. A device, comprising:
a semiconductor integrated circuit chip arranged on a first surface of a die pad in a substrate, the substrate comprising an array of first electrically conductive leads extending away from the die pad;
an encapsulation of laser direct structuring (LDS) material encapsulating the substrate and the semiconductor integrated circuit chip, wherein the encapsulation has a first surface, a second surface opposed to the first surface and a peripheral surface between the first surface and the second surface, and wherein the array of first electrically conductive leads protrudes from the peripheral surface of the encapsulation with areas of the second surface of the encapsulation arranged between adjacent leads in the array of first electrically conductive leads; and
LDS structured areas of the second surface of the encapsulation located between adjacent leads in the first array of electrically conductive leads, the LDS structured areas of the second surface of the encapsulation of LDS material providing an array of second electrically conductive leads exposed at the second surface of the encapsulation.

12. The device of claim 11, wherein the die pad has a second die pad surface opposed to the first die pad surface, the second die pad surface left exposed at the second surface of the encapsulation, and wherein the array of second electrically conductive leads is arranged around the second die pad surface.

13. The device of claim 11, further comprising an electrical connection pattern between the semiconductor integrated circuit chip and the array of first electrically conductive leads and the array of second electrically conductive leads.

14. The device of claim 11, further comprising a wire bonding pattern between the semiconductor integrated circuit chip and the array of first electrically conductive leads and the array of second electrically conductive leads.

15. The device of claim 11, further comprising:
first electrically conductive vias extending through the encapsulation material between the first surface of the encapsulation and the array of first electrically conductive leads and the array of second electrically conductive leads;
second electrically conductive vias extending through the encapsulation material between the first surface of the encapsulation and the semiconductor integrated circuit chip; and
a routing of electrically conductive lines electrically coupling selected ones of the first electrically conductive vias with selected ones of the second electrically conductive vias.

16. The device of claim 11, wherein leads in the array of second electrically conductive leads protruding from the peripheral surface of the encapsulation are bent to provide lead distal portions substantially co-planar with the array of second electrically conductive leads exposed at the second surface of the encapsulation.

17. The device of claim 11, wherein the substrate further comprises an array of second electrically conductive leads extending away from the die pad, and wherein the array of second electrically conductive leads exposed at the second surface of the encapsulation are in contact with the third electrically conductive leads.
